(19) United States
(12) Patent Application Publication
(10) Pub. No.: US 2006/0197176 A1
(43) Pub. Date: Sep. 7, 2006

(54) Electronic subassembly having conductive layer, conductive film and method of making the same

(75) Inventor: Ching-Lung Yang, San Chung City (TW)

Correspondence Address: TROXELL LAW OFFICE PLLC, SUITE 1404, 5205 LEESBURG PIKE, FALLS CHURCH, VA, 22041, US

(73) Assignee: Cateron Corporation

(21) Appl. No.: 11/188,859

(22) Filed: Jul. 26, 2005

(30) Foreign Application Priority Data
Mar. 2, 2005 (TW) 094106333

(51) Int. Cl. H01L 29/00

(52) U.S. Cl. 257/508

(57) ABSTRACT

The present invention relates to an electronic subassembly having a conductive layer, a conductive film and a method of making the same. The conductive film includes a supporting layer (31), a conductive layer (32) and a connection layer (33), all of which are orderly stacked. The connection layer (33) is formed on the conductive layer (32) and attaches the conductive film to the electronic subassembly. The supporting layer (31) will be peeled off after the conductive film adheres to the electronic subassembly. Thus, both two sides of the conductive layer (32) can be electrically connected to a ground circuit of the electronic subassembly, and the electronic subassembly has good electromagnetic shielding performance. Because the supporting layer (31) will be peeled off after the conductive film adheres to the electronic subassembly, there remains only the connection layer (33) and the conductive layer (32) on the electronic subassembly, the thickness of the electronic subassembly with the conductive film thereon is reduced.

### BACKGROUND OF THE INVENTION

1. Field of the Invention

The present invention relates to an electronic subassembly having a conductive layer, a conductive film for use in the electronic subassembly and a method of making the same, and more particularly to a conductive film having good grounding effect and electromagnetic interference protection.

2. Description of the Related Arts

In conventional electronic devices, a conductive film is widely used to shield electromagnetic interference. A conventional conductive film includes at least a ground layer. The ground layer is generally made of metal material. Since the thickness of the ground layer is very thin, the conductive film is typically of multi-layer configuration to support the ground layer.

Japan Patent Publication No. 2000-269632 discloses a strengthened shielding film. The strengthened shielding film comprises a base layer, a shielding layer formed on a surface of the base layer, and a strengthened layer formed on an opposite surface of the base layer. A printed circuit having the strengthened shielding layer is disposed on a base film. After the printed circuit adheres to the base film through heat and pressure, the strengthened layer is peeled off.

Japan Patent Publication No. 2003-298285 discloses another strengthened shielding film. The strengthened shielding film comprises a base layer, a shielding layer formed on a surface of the base layer, and a strengthened layer formed on an opposite surface of the base layer. The strengthened layer is capable of being peeled off from an adhesive layer made of heat-resistant and dissolve-resistant adhesive material. On a base film, there is attached to the strengthened shielding film, a flexible printed circuit board and so on. A conductive adhesive layer of the shielding layer adheres to a portion of a ground circuit. Then, the strengthened layer is peeled off through heat and pressure.

Regarding the above-mentioned strengthened shielding films, the base layer is exposed by peeled off the strengthened layer. This results in complexity and high cost. Furthermore, the shielding layer only has a few points electrically contacting with the ground circuit, thus contact impedance is large and the shielding effect is adversely affected.

U.S. Pat. No. 6,768,052 discloses a printed circuit board comprising a base layer, a conductive layer formed on a surface of the base layer through a first adhesive agent, a cover layer formed on the conductive layer through a second adhesive agent, and aluminum foil pasted on an upper surface of the cover layer through a conductive adhesive agent. The conductive layer, the conductive adhesive agent and the aluminum foil are used for electromagnetic protection. Since the printed circuit board is of a multi-layer configuration, its manufacturing cost is increased. On the other hand, the aluminum foil is easy to be scraped because it is exposed outside during manufacturing and transmitting procedure. As a result, the electromagnetic shielding performance of the aluminum foil is adversely affected.

Referring to FIG. 1, a conductive film provided by Japan Tatsuta Company is of five-layer configuration. The conductive film comprises a base layer 92 made of phenylene Sulfone (PPS), and a conductive layer 91 formed on a surface of the base layer 92 through sputtering technology. The conductive layer 91 is made of metal material, e.g. argentum or copper. A connection layer 94 is formed on another side of the conductive layer 91. The connection layer 94 may comprise thermosetting epoxy resin. On outside surface of the connection layer 94 and the base layer 92 are respectively attached to a removable film 95 and a supporting layer 93. The removable film 95 protects the connection layer 94 during transportation. The supporting layer 93 supports and protects the conductive film 91 during transportation and before manufacturing procedure.

The conductive layer 91 has a thickness of about 1˜1.5 μm. The base layer 92 has a thickness of about 9 μm. The supporting layer 93 has a thickness of about 30 μm. The connection layer 94 has a thickness of about 20˜25 μm. The removable film 95 has a thickness of about 30 μm. When the conductive film is applied on a printed circuit board, the supporting layer 93 and the removable film 95 are removed. The connection layer 94 adheres to the printed circuit board through thermosetting technology. Finally, the conductive film only reamains the base layer 92, the conductive layer 91 and the connection layer 94. Thus, the conductive film ultimately has a thickness of about 30˜35.5 μm.

When the conductive film is used in the printed circuit board, the base layer 92 made of phenylene sulfone is capable of protecting the conductive layer 91. However, since the phenylene sulfone is a non-conductive material, the conductive layer 91 is electrically connected to the ground through the connection layer 94 and internal circuit of the printed circuit board. Thus, the length of the grounding path is increased and the impedance is correspondingly increased, the shielding effect of the conductive film is adversely affected. On the other hand, when the conductive film is used in the printed circuit board, the base layer 92 is still remained. The thickness of the conductive film cannot be further reduced, which can not comply with the miniature and light trend of current electronic products. Furthermore, the base layer 92 using phenylene sulfone results in high cost.

### SUMMARY OF THE INVENTION

An object of the present invention is to provide an electronic subassembly with a conductive layer, the electronic subassembly having good grounding and electromagnetic protection performance.

Another object of the present invention is to provide a conductive film having a thin thickness, good grounding and electromagnetic protection effect, and low manufacturing cost.

Yet another object of the present invention is to provide a method of making a conductive film having good electromagnetic protection performance, the manufacturing procedure being simplified and the manufacturing cost being reduced.

In order to achieve the above-mentioned objects, a conductive film in accordance with the present invention comprises a supporting layer, a conductive layer and a connection layer, all of which are orderly stacked. The connection layer is formed on the conductive layer and attaches the conductive film to the electronic subassembly. The supporting layer will be peeled off after the conductive film adheres to the electronic subassembly. Thus, both two sides of the conductive layer can be electrically connected to a ground circuit of the electronic subassembly, and the conductive film has good electromagnetic shielding performance.

The supporting layer is made of heat-labile material with low glutinosity, such as Polyethylen-theraphthalat. Conductive material, such as argentum or copper, is pasted on a surface of the supporting layer through electrolytic plating, sputtering or evaporating to form the conductive layer. In order to increase oxidation resistance performance and wearability of the conductive layer, an additional metal layer with oxidation resistance performance may be formed between the supporting layer and the conductive layer. The conductive layer may be an aluminum foil directly attaching to the supporting layer. The connection layer may be made of epoxy resin material having a plurality of tiny conductive granules. A removable film may be disposed on an outside surface of the connection layer to protect the connection layer from being contaminated. Each layer has a preferred thickness as follows: the thickness of the supporting layer is about 30 μm, the thickness of the conductive layer is about 3 μm, and the thickness of the connection layer is about 15˜25 μm. If the conductive layer is aluminum foil, the thickness of the conductive layer is about 6 μm.

A method of making a conductive film with electromagnetic protection in accordance with the present invention comprises the following steps: a) plating a conductive layer made of Argentum or Copper on a supporting layer; b) pasting a connection layer made of epoxy resin material on the conductive layer; and c) performing a specific operation. The operation may comprise a heating operation, for example, heating the epoxy resin to a first range of temperature. The first range of temperature is 40° C.˜130° C.

Before the step a), a metal layer with oxidation resistance performance may be plated on the supporting layer. Conductive material, such as argentum or copper, is pasted on a surface of the supporting layer through electrolytic plating, sputtering or evaporating to form the conductive layer. The epoxy resin material has a plurality of tiny conductive granules.

If the conductive layer is aluminum foil, a method of making the conductive film with the aluminum foil comprises the following steps of: a) disposing aluminum foil on a conductive layer; b) pasting a connection layer made of epoxy resin material on the conductive layer; and c) performing a specific operation to the epoxy resin. The operation may comprise a heating operation, for example, heating the epoxy resin to a first range of temperature. The first range of temperature is 40° C.˜130° C.

Compared to the conventional technology, both two sides of the conductive layer can be electrically connected to a ground circuit of the electronic subassembly, thus the conductive film has good electromagnetic shielding performance. After the conductive film adheres to the electronic subassembly, there remains only the connection layer and the conductive layer on the electronic subassembly, the thickness of the electronic subassembly with the conductive film thereon is reduced.

### BRIEF DESCRIPTION OF THE DRAWINGS

FIG. 1 is a cross section view showing a conventional conductive film;

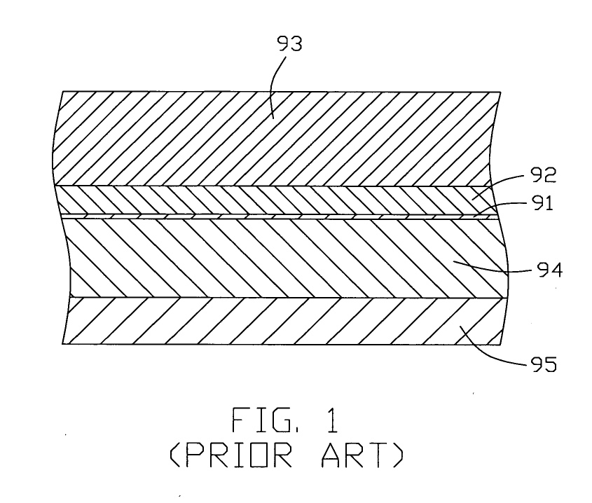

FIG. 2 is a cross section view showing a conductive film of the present invention;

FIG. 3 is a cross section view showing the conductive film of the present invention attached to a printed circuit board;

FIG. 4 is a cross section view showing the conductive film of FIG. 3 when it is heated; and

FIG. 5 is a cross section view showing the conductive film of the present invention attached to the printed circuit board with a supporting layer thereof being removed.

### DESCRIPTION OF THE PREFERRED EMBODIMENT

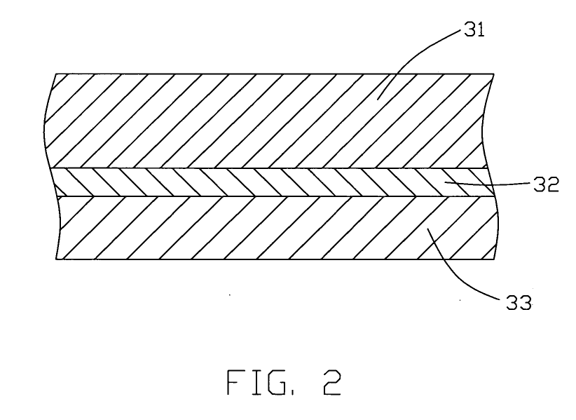

Referring to FIG. 2, a conductive film with electromagnetic protection performance in accordance with the present invention comprises a supporting layer 31, a conductive layer 32 and a connection layer 33, all of which are orderly stacked. The supporting layer 31 is made of heat-labile material with low glutinosity, such as Polyethylen-Theraphthalat (PET). When the connection layer 33 adheres to a printed circuit board through thermosetting technology, the supporting layer 31 will warp and can not keep a compact connection with the conductive layer 32 because the supporting layer 31 is made of heat-labile material. Therefore, after the conductive film adheres to the printed circuit board through thermosetting technology, the supporting layer 31 can be removed to expose the conductive layer 32. The conductive layer 32 is made of conductive material, such as argentum, copper and so on. The conductive material is plated on a surface of the supporting layer 31 through electrolytic plating, sputtering or evaporating to form the conductive layer 32. In order to increase oxidation resistance performance and wearability of the conductive layer 32, an additional metal layer (not shown) with oxidation resistance performance may be plated on an upper surface of the conductive layer 32. The metal layer is made of metal material with oxidation resistance, such as nickel. The conductive layer 32 may be aluminum foil directly attaching to the supporting layer 31. The connection layer 33 may be made of epoxy resin material having a plurality of tiny conductive granules. A removable film (not shown) is disposed on an outside surface of the connection layer 33 to protect the connection layer 33 from being contaminated during transportation and manufacturing procedure.

A method of making the conductive film in accordance with the present invention comprises the following steps: a) plating a conductive layer 32 made of argentum or copper on a supporting layer 31; b) pasting a connection layer 33 made of epoxy resin material on the conductive layer 32; and c) performing a specific operation to the epoxy resin. The specific operation may comprise a heating operation, for example, heating the epoxy resin to a first range of temperature. The first range of temperature is 40° C.˜130° C.

In the step a), a metal layer with oxidation resistance performance may be plated on the supporting layer 31, and then the conductive layer 32 made of argentum or copper is formed on the supporting layer 31. After the step c), a removable film may be disposed on an outside surface of the connection layer 33 to protect the connection layer 33 from being contaminated.

If the conductive layer is aluminum foil, a method of making the conductive film with the aluminum foil comprises the following steps of: a) disposing aluminum foil on a conductive layer 32; b) pasting a connection layer 33 made of epoxy resin material on the conductive layer 32; and c) performing a specific operation to epoxy resin. The operation may comprise a heating operation, for example, heating the epoxy resin to a first range of temperature. The first range of temperature is 40° C.˜130° C.

After the step c), a removable film may be disposed on an outside surface of the connection layer 33 to protect the connection layer 33 from being contaminated.

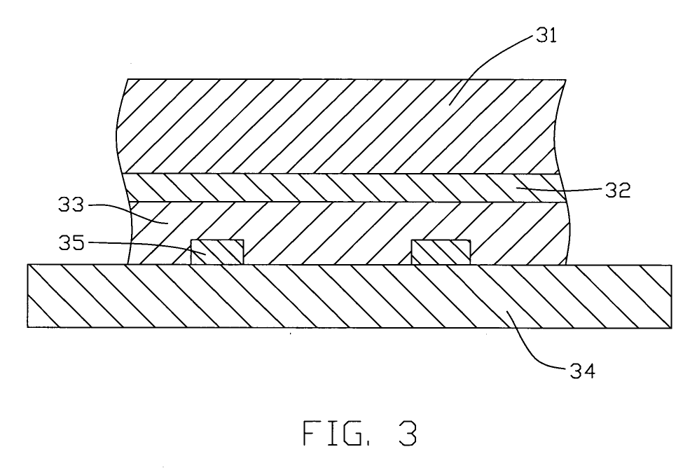

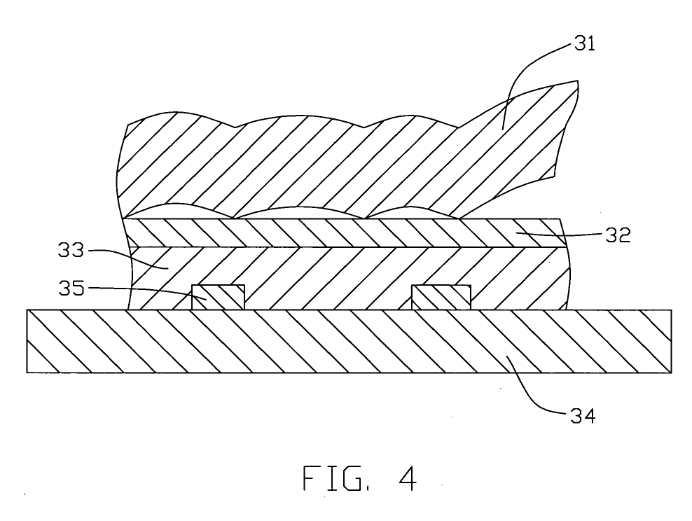

Referring to FIGS. 3 and 4, when using the conductive film of the present invention, the connection layer 33 is disposed on a printed circuit board 34. The conductive film is then heated to a second range of temperature, e.g. 180° C.˜220° C., which is kept for a predetermined time, e.g. thirty minutes. At the same time, a pressure, e.g. 100 kilogram/square centimeter, is exerted on the conductive film in a direction toward the printed circuit board 34, to make the epoxy resin solidify and adhere to the printed circuit board 34. Electrical connection between the conductive layer 32 and the grounding pads 35 of the printed circuit board 34 is established by conductive granules (not shown) of the epoxy resin. During the heating process, the supporting layer 31 warps and can not keep a compact contact with the conductive layer 32 because the supporting layer 31 is made of heat-labile material. Therefore, after the conductive film adheres to the printed circuit board through thermosetting technology, the supporting layer 31 can be removed to expose the conductive layer 32. When the printed circuit board 34 with the conductive film formed thereon is applied on an electronic device, the conductive layer 32 is electrically connected to the ground through a contact between the outside surface of the conductive layer 32 and a shell or other components of the electronic device.

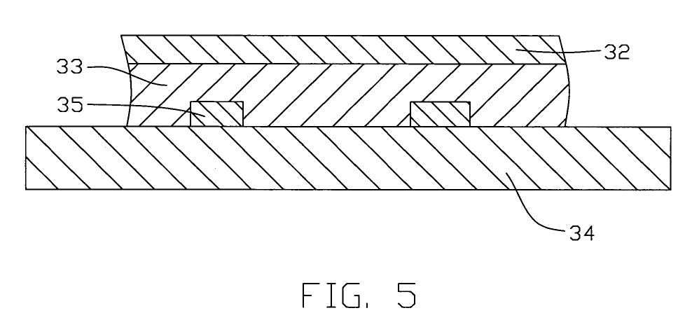

Referring to FIG. 5, when the conductive film is heated, the supporting layer 31 will warp and can be removed, thus only the conductive layer 32 and the connection layer 33 is formed on the printed circuit board 34. The conductive layer 32 is electrically connected to the grounding pads 35 of the printed circuit board 34 through conductive granules of the epoxy resin. Furthermore, the conductive layer 32 is electrically connected to the ground through a contact between the outside surface of the conductive layer 32 and a shell or other components of the electronic device. Therefore, the grounding effect is greatly enhanced.

Both upper and lower surfaces of the conductive layer 32 can be electrically connected to the ground, so the conductive film has good shielding performance. Furthermore, when the conductive film is heated, the supporting layer 31 can be removed, thus only the conductive layer 32 and the connection layer 33 is formed on the printed circuit board 34. Accordingly, the thickness of the conductive film is thinner than the conventional conductive film. The conductive film made by the method of the present invention comprises several layers each having a preferred thickness as follows: the thickness of the supporting layer 31 is about 30 μm, the thickness of the conductive layer 32 is about 3 μm, and the thickness of the connection layer 33 is about 15˜25 μm. If the conductive layer 32 is aluminum foil, the thickness of the conductive layer 32 is about 6 μm. When the conductive film is used in the printed circuit board 34, only the conductive layer 32 and the connection layer 33 is remained, thus the thickness of the conductive film is about 18˜28 μm. If the conductive layer 32 is aluminum foil, the thickness of the conductive film is about 21˜31 μm.

What is claimed is:

1. An electronic subassembly comprising:
an electronic element having a grounding circuit; and
a conductive layer having a first surface and a second surface, the first surface electrically connected to the grounding circuit of the electronic element, the second surface exposed outside and electrically connected to another grounding path to establish an electrical connection with the grounding circuit.

2. The electronic subassembly as claimed in claim 1, further comprising a connection layer formed on the conductive layer, the connection layer electrically connecting the conductive layer to the grounding circuit of the electronic element.

3. The electronic subassembly as claimed in claim 2, wherein the connection layer is made of epoxy resin and has a plurality of tiny conductive granules.

4. The electronic subassembly as claimed in claim 1, wherein the conductive layer is made of metal material.

5. The electronic subassembly as claimed in claim 1, wherein the electronic element is a printed circuit board.

6. A conductive film for use in an electronic element, comprising:
a conductive layer; and
a connection layer connecting with the conductive layer and adapted for adhering the conductive film to the electronic element;
wherein the conductive layer has opposite sides both connecting to a grounding circuit of the electronic element.

7. The conductive film as claimed in claim 6, wherein the conductive layer is aluminum foil.

8. The conductive film as claimed in claim 6, wherein the connection layer is made of epoxy resin and has a plurality of tiny conductive granules.

9. The conductive film as claimed in claim 6, further comprising a removable film disposed on an outside surface of the connection layer for preventing the connection layer from being contaminated before the conductive film is attached to the electronic element.

10. The conductive film as claimed in claim 6, further comprising a supporting layer formed on the conductive layer before the conductive film is attached to the electronic element.

11. The conductive film as claimed in claim 10, wherein the supporting layer is made of heat-labile material with low glutinosity.

12. The conductive film as claimed in claim 11, wherein the supporting layer is made of Polyethylen-theraphthalat.

13. The conductive film as claimed in claim 10, wherein the conductive layer is formed by electrolytic plating, sputtering or evaporating.

14. The conductive film as claimed in claim 10, further comprising a metal layer with oxidation resistance performance formed between the conductive layer and the supporting layer.

15. The conductive film as claimed in claim 14, wherein the metal layer is made of nickel.

16. A method of making a conductive film having a supporting layer, a conductive layer and a connection layer, the method comprising the steps of:
a) plating the conductive layer on the supporting layer;
b) pasting the connection layer on the conductive layer; and
c) performing a specific operation to the connection layer.

17. The method as claimed in claim 16, wherein the supporting layer is made of heat-labile material with low glutinosity.

18. The method as claimed in claim 17, wherein the supporting layer is made of Polyethylen-theraphthalat.

19. The method as claimed in claim 16, further comprising a step of plating a metal layer with oxidation resistance performance on the supporting layer before the step a).

20. The method as claimed in claim 19, wherein the metal layer is made of nickel.

21. The method as claimed in claim 16, wherein the conductive layer is formed through electrolytic plating, sputtering or evaporating.

22. The method as claimed in claim 16, wherein the connection layer is made of epoxy resin and has a plurality of tiny conductive granules.

23. The method as claimed in claim 16, wherein the specific operation is a heating operation.

24. The method as claimed in claim 23, wherein the heating operation is heating the connection layer to a range of temperature 40° C.˜130° C.

25. A method of making a conductive film having a supporting layer, a conductive layer and a connection layer, the method comprising the steps of:
a) disposing the conductive layer on the supporting layer;
b) pasting the connection layer on the conductive layer; and
c) performing a specific operation to the connection layer.

26. The method as claimed in claim 25, wherein the conductive layer is aluminum foil.

27. The method as claimed in claim 25, wherein the supporting layer is made of heat-labile material with low glutinosity.

28. The method as claimed in claim 27, wherein the supporting layer is made of Polyethylen-theraphthalat.

29. The method as claimed in claim 25, wherein the connection layer is made of epoxy resin and has a plurality of tiny conductive granules.

30. The method as claimed in claim 25, wherein the specific operation is a heating operation.

31. The method as claimed in claim 30, wherein the heating operation is heating the connection layer to a range of temperature 40° C.˜130° C.
